(19) United States
(12) Patent Application Publication
(10) Pub. No.: US 2015/0137667 A1
(43) Pub. Date: May 21, 2015

(54) CERAMIC MATERIAL, SINTER, CERAMIC DEVICE, PIEZOELECTRICITY CERAMIC BIMORPH AND GLUING METHOD THEREOF

(71) Applicant: Shaohua Su, Shenzhen (CN)

(72) Inventor: Shaohua Su, Shenzhen (CN)

(73) Assignee: AAC TECHNOLOGIES PTE. LTD., Singapore (SG)

(21) Appl. No.: 14/539,073

(22) Filed: Nov. 12, 2014

(30) Foreign Application Priority Data
Nov. 15, 2013 (CN) 201310572270.5

(51) Int. Cl. H01L 41/187; H01L 41/43; H01L 41/333

(52) U.S. Cl. CPC H01L 41/1876; H01L 41/333; H01L 41/43
USPC 310/358; 252/62.9 PZ; 264/614

(57) ABSTRACT

The present disclosure provides a piezoelectricityity ceramic material. The piezoelectricityity ceramic material includes main components that are represented by a general chemical formula of Pb(Mn_{1/3}Sb_{2/3})ₓZr_{y}Ti_{z}O₃+awt % WO₃ and satisfy the following conditions: 0.02 ≦x≦0.1, 0.4≦y≦0.6, 0.4≦z≦0.6, and 0.5≦a≦3. Compared to related art, the products provided by the present disclosure have the following advantages: higher temperature stability, simpler production process, shorter production cycle, and convenient for mass production.

### FIELD OF THE INVENTION

The present disclosure generally relates to a piezoelectricity ceramic material, sinter and method for processing same, piezoelectricity ceramic device with excellent piezoelectricity properties, piezoelectricity ceramic device bimorph and gluing method for improving the temperature stability thereof.

### DESCRIPTION OF RELATED ART

Since the lead zirconate-titanate (PZT) piezoelectricity ceramic was first found in 1954, many countries such as US, Japan, and Holland have made exhaustive studies on the piezoelectricity ceramic system, and with the development of the studies, a series of PZT piezoelectricity ceramic materials with excellent properties have been derived and the application scope of piezoelectricity ceramic materials has also been greatly expanded. Among them, ternary or quaternary system piezoelectricity ceramic based on PZT modified by various elements emerge at the right moment.

In order to obtain high-performance piezoelectricity ceramics, the modified A site (Pb) or B site (Zr, Ti) of Pb(Zr, Ti)O₃ are mostly partially replaced and the ratio of Zr/Ti is changed in order to adjust the properties now. It is processed mostly by common solid sintering, that is, blending a precalcined powder and a certain amount of a binder, dry-pressing and then sintering the mixture. The sintering method cannot satisfy the increasingly diversified and complicated requirements of piezoelectricity members and devices, requires high sintering temperature (1200° C.-1300° C.), and is not favorable to reduce cost. Moreover, PbO volatizes seriously during sintering, which not only damages human health and pollutes the environment, but also results in the deviation of actual composition and thus changes the properties. The volatilization of lead also corrodes the heating rod of the sintering machine and reduces the service life of the machine.

With the development of the surface mount technology (SMT), multi-layer piezoelectricity ceramics gain popularity in the market due to their high efficiency, miniaturization, and function integration. This requires that the inner electrode and the ceramic must be co-fired together. The melting point of silver is 961° C. Based on the aforesaid temperature, Ag/Pd alloy is generally used as the co-fired electrode. With the increase of Pd content, the price of Pd will result in a sharp rise in the product cost.

Except for the high piezoelectricity properties, the temperature stability of the ceramic is also required higher and higher in a modern piezoelectricity device. In order to improve the temperature stability of the ceramic, traditional method mainly realized by adjusting the formula of the ceramic, includes the following methods: \textcircled{1} adjust Zr/Ti ratio, a M point with good temperature stability exists around the phase boundary of ceramics. With the transition from a tetragonal to a rhomb, a scope of the temperature stability of the ceramic turning bad rapidly exists. The M point is positioned in the scope and more closing to a side of the tetragonal. \textcircled{2} Mix and modify additive. The additive, such as CoO₂, Cr₂O₃, CeO₂, MnO₂ and so on, makes the cell structure of ceramics generate distortion. Due to the distortion of the cell structure, the domain wall of the cell structure is beneficial to be redirected and is easier to move, and the stress in the domain is easier to be released. \textcircled{3} Ion-exchange, e.g. use Ni²⁺, Mn²⁺, Mg²⁺ to exchange Pb²⁺ for generating an oxygen vacancy so as to reduce the size of a cell of ceramics and make the electric domain movement become more difficult, but the temperature stability of the ceramic becomes more better.

Traditional method mainly adjusts the formula of ceramics to improve the temperature stability thereof. Products processed by the traditional method are difficult to be produced and have a long production cycle. In addition, the temperature stability of the product is undesired and does not satisfy the requirement of the development of electronics. With the adjustment of the Zr/Ti ratio of the ceramic, a little change of a M point will result in a big change of the performance of the ceramic. Thus, in order to obtain good performance of the ceramic, the process condition must be controlled strictly.

### BRIEF DESCRIPTION OF THE DRAWINGS

Many aspects of the embodiment can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a microstructure of a cross-section of a piezoelectricity ceramic according to an exemplary embodiment of the present disclosure.

FIG. 2 shows an energy spectrum of the ceramic cross-section of FIG. 1.

FIG. 3 is a schematic view illustrating the structure of a piezoelectricity ceramic bimorph.

FIG. 4 shows comparison between temperature stabilities of a piezoelectricity ceramic and a piezoelectricity ceramic bimorph of the present disclosure.

### DETAILED DESCRIPTION OF THE INVENTION

The technical solutions in the embodiments of the present disclosure are explicitly described in detail below. Obviously, the described embodiments are only a part of rather than all of the embodiments of the present disclosure. Based on the embodiments in the present disclosure, all other embodiments occurred to those of ordinary skill in the art without creative work fall within the scope of the present disclosure.

The present disclosure provides a piezoelectricity ceramic material, comprising main components that are represented by a general chemical formula of

Pb(Mn_{1/3}Sb_{2/3})ₓZr_{y}Ti_{z}O₃+awt % WO₃

wherein following conditions are satisfied:

0.02≦x≦0.1, 0.4≦y≦0.6, 0.4≦z≦0.6, and 0.5≦a≦3.

Also, the present disclosure provides a method for processing a piezoelectricity ceramic sinter from the aforesaid piezoelectricity ceramic material, wherein by controlling the particle sizes of the raw material and the precalcined powder, a desired piezoelectricity ceramic sinter is obtained by casting forming; and then a desired piezoelectricity ceramic device is obtained by polarizing the piezoelectricity ceramic sinter in silicone oil with a polarization electric field ranging from 4000 to 6000 V/mm for 20 minutes, and the temperature of the silicone oil is substantially 120° C. Specifically, the method comprises the following steps:

Step S1, material preparation: providing the components of a piezoelectricity ceramic material according to a chemical formula of Pb(Mn_{1/3}Sb_{2/3})ₓZr_{y}Ti_{z}O₃+awt % WO₃ wherein x represents a mole ratio of (Mn_{1/3}Sb_{2/3}) in the chemical formula and 0.02≦x≦0.1, y represents a mole ratio of Zr in the chemical formula and 0.4≦y≦0.6, z represents a mole ratio of Ti in the chemical formula and 0.4≦z≦0.6, awt % represents a weight ratio of WO₃ relative to the chemical formula of Pb(Mn_{1/3}Sb_{2/3})ₓZr_{y}Ti_{z}O₃ and 0.5≦a≦3, and pulverizing the components into a powder, the components comprising Pb₃O₄, MnCO₃, Sb₂O₃, ZrO₂, TiO₂, and WO₃.

The masses of the components as the raw materials are calculated according to the ratios as set forth in the chemical formula and weighed using a precision electronic balance. The median particle size of the aforesaid components is controlled below 2 μm by raw material selection or ball-mill mixing so as to improve the reactivity of the raw material, and the aforesaid components should be oven-dried substantially 24 hours at 120° C. in an oven.

Step S2, mixing: adding distilled water into the aforesaid processed powder in a mass ratio of substantially 1:1, mixing them for substantially 8 hours, and then oven-drying the mixture.

The processed powder and distilled water are mixed in a ball mill so as to provide a more uniform mixing.

Step S3, calcination: calcining the aforesaid oven-dried product at 800-900° C. for substantially 3 hours to synthesize a calcined product.

Step S4, pulverizetion: pulverizing the aforesaid calcined product to form a mixture and oven-drying the mixture.

In the pulverizetion step, the aforesaid calcined product is pulverized by micro-bead ball mill. The micro-bead ball mill increases the specific surface area of the powder, enhances the activity of the powder, increases the driving force of sintering, and in turn reduces the ceramic sintering temperature.

Step S5, pulping: adding a binder, a plasticizer, a dispersing agent, and a solvent into the aforesaid mixture and mixing them to form a ceramic pulp.

Wherein, the binder, plasticizer, dispersing agent, and solvent added during the pulping are as shown in Table 1 below.

TABLE 1

| | | | Percentage | |
|---|---|---|---|---|
| Times | Name | Function | (%) | Duration |
| The First Time | Powder | | 100 | 12 H |
| | Toluene | Solvent | 30-40 | |
| | Alcohol | Solvent | 10-20 | |
| | Menhaden oil | Dispersing | 0.1-1 | |
| | | agent | | |
| The Second Time | Polyvinyl butyral | Binder | 3-8 | 12 H |
| | (PVB) | | | |
| | Dibutyl phthalate | Plasticizer | 1-5 | |
| | (DBP) | | | |

Step S6, forming: debubbling the ceramic pulp and then casting it into a ceramic film.

There are four main methods for forming ceramic film: rolling film forming, casting forming, dry pressing forming, and hydrostatic forming. Rolling film forming is applicable to sheet members; casting forming is applicable to thinner members where the film thickness may be less than 10 μm; dry pressing forming is applicable to block members; hydrostatic forming is applicable to irregular or block members. Apart from hydrostatic forming, all the other forming methods require a binder which is about 3% relative to the weight of the raw material. After forming, it is required to remove the binder. The binder only facilitates forming, but it is a highly reducing substance, which, after forming, shall be removed to prevent it from affecting the sintering quality.

Step S7, laminating: laminating the aforesaid ceramic film to form a laminated product.

Step S8, sintering: firing the laminated product at 1100-1200° C. for substantially 3 hours to form a piezoelectricity ceramic sinter.

For illustrating the present disclosure more detailed, a chemical formula of a piezoelectricity ceramic material, such as Pb(Mn_{1/3}Sb_{2/3})_{0.08}Zr_{0.50}Ti_{0.42}O₃+1 wt % WO₃, is provided.

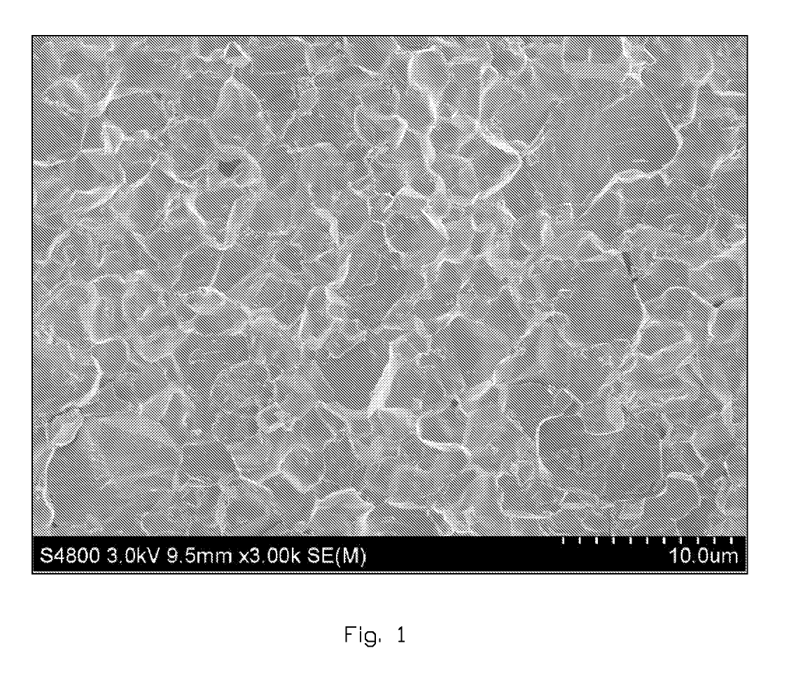

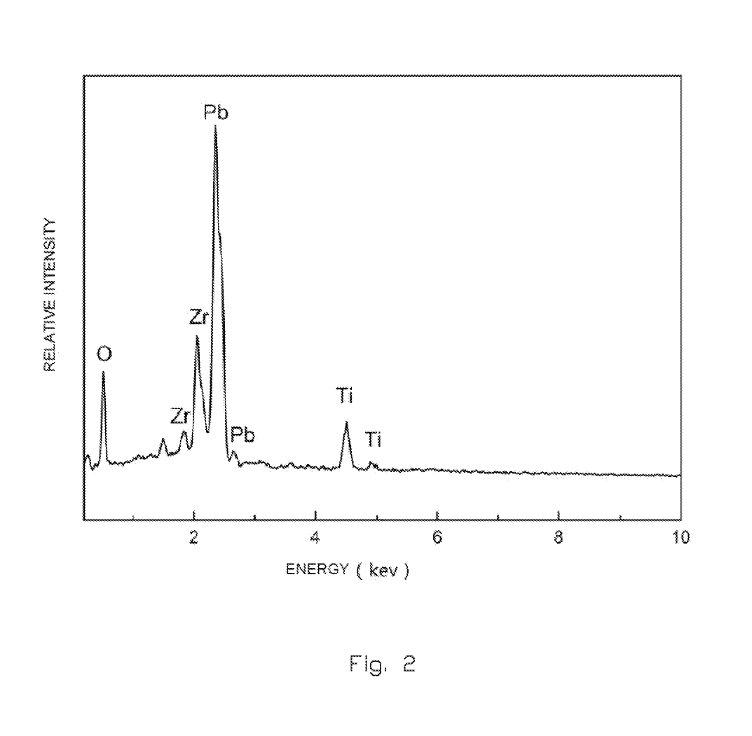

As shown in FIG. 1, which shows a microstructure of a cross-section of the piezoelectricity ceramic of the aforesaid exemplary embodiment, and the piezoelectricity ceramic is processed by the aforesaid process method. As can be seen, the piezoelectricity ceramic is sintered compactly, the fracture mechanism is mainly transcrystalline fracture, and the crystal size is about 3-4 μm. Referring to FIG. 2, an energy spectrum analysis of a cross-section of the piezoelectricity ceramic shows that the main components include Pb, Ti, Zr, and O.

The present disclosure further provides a piezoelectricity ceramic device formed by electrode polarizing the aforesaid piezoelectricity ceramic sinter. The piezoelectricity ceramic device is obtained by polarizing the aforesaid piezoelectricity ceramic sinter in silicone oil with a polarization electric field ranging from 4000 to 6000 V/mm for 20 minutes, and the temperature of the silicon oil is substantially 120° C.

The piezoelectricity ceramic device is tested according to the national standard and the piezoelectricity properties are calculated, wherein the test results of the samples are shown in Table 2 in detail.

TABLE 2

| | | |
|---|---|---|
| Relative dielectric constant | ∈ᵣ₃^{T} | 1246 |
| Dielectric loss | tanδ | 0.67% |
| Electromechanical coupling coefficient | Kₚ(radical) | 0.5 |
| | kₜ(thickness) | 0.39 |
| | k₃₁(length) | 0.29 |
| Piezoelectricity constant | d₃₃(pC/N) | 259 |
| | d₃₁(pC/N) | −113 |
| Mechanical quality factor | Qm | 1213 |
| Elasticity compliance coefficient | S^{E}₁₁(10⁻¹² m²/N) | 13.4 |
| | S^{E}₁₂(10⁻¹² m²/N) | −4.2 |
| Piezo voltage coefficient | g₃₁(10⁻³ Vm/N) | 10.3 |
| | g₃₃(10⁻³ Vm/N) | 23.5 |
| Frequency constant | Nd(Hz*m) | 2275 |
| Poisson's ratio | σ | 0.31 |
| Density | ρ (g/cm³) | 7.9 |

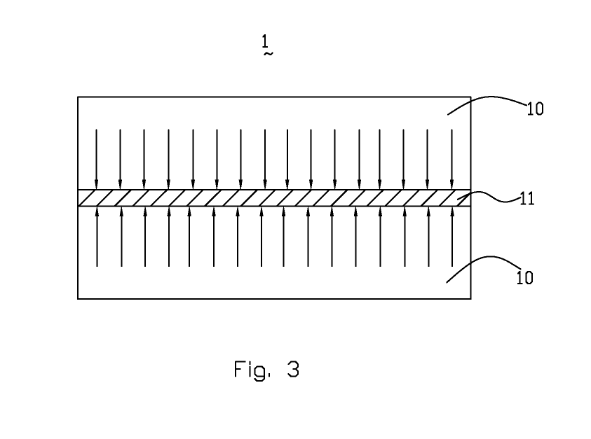

Referring to FIG. 3, the present disclosure provides a piezoelectricity ceramic bimorph 1 formed by gluing two pieces of piezoelectricity ceramic devices 10 in their opposite polarization direction (The direction of the arrows represents the direction of polarization as shown in FIG. 3).

The present disclosure further provides a gluing method for improving the temperature stability of the piezoelectricity ceramic bimorph 1, including the following steps:

Step 1, placing a polarized piezoelectricity ceramic device 10 in greenhouse for at least 24 hours.

Step 2, printing an expoxy adhesive 11 on a surface of one of the placed piezoelectricity ceramic device 10 by screen printing, and then bonding another of the placed piezoelectricity ceramic device 10 with the aforesaid placed piezoelectricity ceramic device 10 in their opposite polarization direction.

Step 3, pressurizedly welding two pieces of the bonded piezoelectricity ceramic devices 10 under room temperature for bonding them completely.

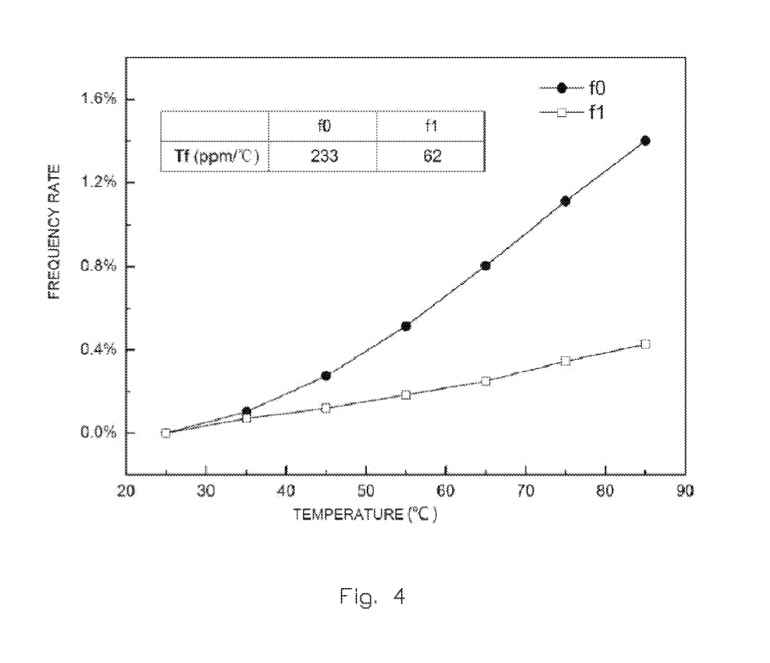

Referring to FIG. 4, f0 is a frequency of a piezoelectricity ceramic device, and f1 is a frequency of a piezoelectricity ceramic bimorph. As can be seen, compared with the piezoelectricity ceramic device, the temperature stability of the piezoelectricity ceramic bimorph is improved obviously.

For a piezoelectricity vibrator, the resonant frequency fᵣ is:

$$fr = \frac{1}{2 l} \sqrt{\frac{1}{ρ {S}_{11}^{E}}}$$

Wherein l is a length of the piezoelectricity vibrator, p is a density of the piezoelectricity vibrator, and S₁₁^{E} is an elasticity compliance coefficient of the piezoelectricity vibrator. As can be seen, due to the size, density, and elasticity compliance coefficient of the piezoelectricity vibrator are changed with temperature, fᵣ is also changed with temperature. For a piezoelectricity ceramic bimorph, it mainly includes a piezoelectricity ceramic device and an expoxy adhesive. But, because the expoxy adhesive relative to the piezoelectricity ceramic device has a bigger expansion coefficient, the frequency temperature coefficient of the expoxy adhesive relative to that of the piezoelectricity ceramic bimorph is negative. However, the frequency temperature coefficient of the piezoelectricity ceramic device relative to that of the piezoelectricity ceramic bimorph is positive. Therefore, in a piezoelectricity ceramic bimorph, the frequency temperature coefficient of the expoxy adhesive and the frequency temperature coefficient of the piezoelectricity ceramic device are neutralized partially. Consequently, the frequency temperature coefficient of the piezoelectricity ceramic bimorph is near to zero, and the temperature stability of the piezoelectricity ceramic bimorph is improved.

Compared to related art, the products processed by the process method of the present disclosure include the following advantages: a higher temperature stability, a simpler production process, a shorter production cycle, and convenient for mass production.

While the present disclosure has been described with reference to the specific embodiments, the description of the invention is illustrative and is not to be construed as limiting the invention. Various of modifications to the present invention can be made to the exemplary embodiments by those skilled in the art without departing from the true spirit and scope of the invention as defined by the appended claims.

What is claimed is:

1. A piezoelectricity ceramic material, comprising main components that are represented by a general chemical formula of
Pb(Mn_{1/3}Sb_{2/3})ₓZr_{y}Ti_{zO}₃+awt % WO₃
and satisfy the following conditions:
0.02≦x≦0.1, 0.4≦y≦0.6, 0.4≦z≦0.6, and 0.5≦a≦3.

2. A method for processing a piezoelectricity ceramic sinter obtained by sintering the piezoelectricity ceramic material of claim 1, comprising the following steps:
Step 1, material preparation: providing the components of a piezoelectricity ceramic material according to a chemical formula of Pb(Mn_{1/3}Sb_{2/3})ₓZr_{y}Ti_{zO}₃+awt % WO₃ wherein 0.02≦x≦0.1, 0.4≦y≦0.06, 0.4≦z≦0.6, 0.5≦a≦3 and pulverizing the components into a powder, the components comprising Pb₃O₄, MnCO₃, Sb₂O₃, ZrO₂, Ti O₂, WO₃;
Step 2, mixing: adding distilled water into the aforesaid processed powder in a mass ratio of substantially 1:1, mixing them for substantially 8 hours, and then oven-drying them;
Step 3, calcination: calcinating the aforesaid oven-drying product at 800-900° C. for substantially 3 hours to synthesize a calcined product;
Step 4, pulverizetion: pulverizing the aforesaid calcined product to form a mixture and oven-drying the mixture;
Step 5, pulping: adding a binder, a plasticizer, a dispersing agent, and a solvent into the aforcesaid mixture and mixing them to form a ceramic pulp;
Step 6, forming: debubbling the ceramic pulp and then casting it into a ceramic film;
Step 7, laminating: laminating the aforesaid ceramic film to form a laminated product;
Step 8, sintering: firing the laminated product at 1100-1200° C. for substantially 3 hours to form a piezoelectricity ceramic sinter.

3. The method for processing a piezoelectricity ceramic sinter of claim 2, wherein in the step of material preparation, the components are pulverized into a powder by raw material selection or ball-mill mixing, and the median particle size of the powder is controlled below 2 μm.

4. The method for processing a piezoelectricity ceramic sinter of claim 2, wherein in the step of mixing, the processed powder and the distilled water are mixed in a ball mill.

5. The method for processing a piezoelectricity ceramic sinter of claim 2, wherein in the step of pulverizetion, using a micro-sphere ball millto pulverizing the aforesaid calcined product, and the median particle size of the pulverized calcined product is controlled below 1 μm.

6. A piezoelectricity ceramic device formed by electrode polarizing a piezoelectricity ceramic sinter of claim 2.

7. The piezoelectricity ceramic device as claimed in claim 6, wherein the piezoelectricity ceramic device is obtained by polarizing the piezoelectricity ceramic sinter in silicone oil with a polarization electric field ranging from 4000 to 6000 V/mm for 20 minutes, and the temperature of the silicone oil is substantially 120° C.

8. A gluing method for improving the temperature stability of a piezoelectricity ceramic bimorph formed by gluing two pieces of the piezoelectricity ceramic devices of claim 6 in their opposite polarization direction, comprising the following steps:
Step 1, placing a polarized piezoelectricity ceramic device in greenhouse for at least 24 hours;
Step 2, printing an expoxy adhesive on a surface of one of the placed piezoelectricity ceramic device by screen printing, and then bonding another of the placed piezoelectricity ceramic device with the aforesaid placed piezoelectricity ceramic device in their opposite polarization direction;
Step 3, pressurizedly welding two pieces of the bonded piezoelectricity ceramic devices under room temperature for bonding them completely.
